(19) United States
(12) Patent Application Publication
(10) Pub. No.: US 2025/0203916 A1
(43) Pub. Date: Jun. 19, 2025

(54) Asymmetric MOSFET Devices

(71) Applicant: pSemi Corporation, San Diego, CA (US)

(72) Inventors: Dheeraj Mohata, San Diego, CA (US); Anil Kumar, San Diego, CA (US); Panglijen Candra, San Diego, CA (US)

(21) Appl. No.: 18/540,531

(22) Filed: Dec. 14, 2023

(51) Int. Cl. H01L 29/78; H01L 29/08; H01L 29/423; H01L 29/66

(52) U.S. Cl. CPC H10D 30/603; H10D 30/0221; H10D 62/151; H10D 64/519

(57) ABSTRACT

Device structures and related fabrication methods for asymmetric MOSFETs that exhibit high BV_{DSS} and low HCI characteristics while substantially improving the poor sub-threshold slope and output resistance R_{OUT} characteristics common to conventional asymmetric MOSFET devices. Embodiments are fabricated by implanting halo and/or LDD dopants on the source-side of an asymmetric MOSFET using at least two different non-90° twist angles, each in a different quadrant. By implanting dopant at different twist angles, dopant is implanted within otherwise shadowed corners, thus essentially eliminating the parasitic transistors within such corners. Optionally, an extra implantation of halo/LDD dopants may be performed at a 90° twist angle. As a result, a non-90°, multi-twist implanted asymmetric MOSFET exhibits improved linearity and an essentially equivalent gain characteristic compared to conventional asymmetric MOSFETs. The novel asymmetric MOSFETs are quite suitable for applications, such as power amplifiers, which require good linearity and gain characteristics.

### BACKGROUND

### (1) Technical Field

This invention relates to electronic integrated circuit (IC) devices, and more particularly to metal-oxide-semiconductor field-effect transistor (MOSFET) devices.

### (2) Background

Virtually all modern electronic products—including laptop computers, mobile telephones, and electric cars—utilize metal oxide-semiconductor field-effect transistor (MOSFET) integrated circuits (ICs), and in many cases MOSFET ICs fabricated using a semiconductor-on-insulator (SOI) process, such as silicon-on-insulator, or germanium-on-insulator, or silicon/germanium-on-insulator (e.g., a SiGe alloy or a layer of Ge on a layer of Si formed on an insulator).

FIG. 1A is a stylized top plan view of a prior art IC structure 100 for a single N-type MOSFET device. A source S, a gate structure G, and a drain D overlay an active region 102 of N+ material in this example (note that contacts to the source S, the gate structure G, and the drain D have been omitted to reduce clutter). Also shown in FIG. 1A is the top side of a body tie region 101 which, in the illustrated example, comprises a P+ doped region within the active region 102 that is connected to the gate structure G by a polysilicon central gate tab 103 (note that the electrical contact to the body tie region 101 is omitted for clarity).

FIG. 1B is a stylized cross-sectional view along line X-X of FIG. 1A. The IC structure 100 includes the active region 102, an insulating buried-oxide (BOX) layer 104, and a substrate 106 (note that the dimensions for the elements of the IC structure 100 are not to scale; some dimensions have been exaggerated for clarity or emphasis). The substrate 106 is typically a semiconductor material such as silicon or high-resistivity silicon. The BOX layer 104 is a dielectric, and is often SiO₂ formed as a “top” surface of the silicon substrate 106. FIG. 1B also shows the source S 108 and the drain D 110 within the active region 102, surrounded by shallow trench isolation (STI) structures 114, with the gate structure G 112 situated on the upper surface of the active region 102. For some applications, the BOX layer 104 may be omitted, such as in bulk silicon MOSFET designs. For some applications, one or more additional layers or regions may be included, such as a trap-rich layer or the like between the substrate 106 and the BOX layer 104.

The illustrated gate structure G 112 includes a conductive layer 120, such as polysilicon or metal, atop an insulating gate oxide (GOX) layer 122. In the illustrated example, the gate structure G 112 is surrounded by dielectric spacers 124. A “P well” or body 126 is defined within the active region 102 situated below the gate structure G 112 and between the source S 108 and the drain D 110. In operation, a “conduction channel” (for an enhancement mode MOSFET) or an “inversion channel” (for a depletion mode MOSFET) is generated within the body 126 between the source S 108 and the drain D 110 and generally proximate to the GOX layer 122 (e.g., within about the top 100 Å of the body 126). A P-type MOSFET device has a similar structure, but with opposite polarities for the dopants.

The BOX layer 104 and the active region 102 (which may include one or more MOSFETs) may be collectively referred to as a “device region” or “substructure” 128 for convenience (noting that other structures or regions may intrude into the substructure 128 in particular IC designs). A superstructure (not shown) of various elements, regions, and structures may be fabricated in known fashion on or above the substructure 128 in order to implement particular functionality. The superstructure may include, for example, conductive interconnections from the illustrated MOSFET to other components (including other MOSFETs) and/or external contacts, passivation layers and regions, and protective coatings.

Well-known improvements to the maximum voltage handling capability of a MOSFET have included use of halo implants and lightly-doped drain (LDD) regions. A halo implant mitigates punch-through while an LDD region mitigates avalanche breakdown. Referring again to the N-type MOSFET example shown FIG. 1B, halo implants 130 are pocket regions implanted with a P type material (which may be P+ type material) that increases a sub-surface electric field to reduce so-called punch-through, or short channel, conduction between the source S and the drain D, thus increasing breakdown voltage. LDD regions 132 are lightly-doped with N type material to extend the source S and drain D underneath the gate G. The LDD regions 132 reduce high electric fields caused by an applied voltage at the drain D, thereby increasing the drain-channel breakdown voltage.

Halo implants and LDD regions are generally formed at a particular stage of MOSFET fabrication after formation of the gate structure 112 by vertical implantation of a suitable dopant. In FIG. 1B, halo implants 130 and LDD regions 132 have been symmetrically formed within the source S and the drain D on both sides of the gate structure 112.

In some applications, such as power amplifiers, it has been found useful to create “asymmetric” MOSFETs which exhibit a higher breakdown voltage BV_{DSS} and reduced hot carrier injection (HCI) issues compared to a symmetric MOSFETs such as is shown in FIG. 1B. HCI is a phenomenon where a charge carrier (electron or hole) gains sufficient kinetic energy to overcome a potential barrier necessary to break an interface state. The charge carriers can become trapped in the gate dielectric of a MOSFET and may permanently change the switching characteristics of the transistor. HCI is one of the mechanisms that adversely affects the reliability of MOSFETs.

FIG. 1C is a stylized cross-sectional view of an asymmetric MOSFET 150. In contrast to conventional vertical halo/LDD dopant implantation, such dopants may be generally implanted at two angles. For example, a first half of an LDD dose may be implanted vertically and a second half may be implanted at a “tilt” angle θ with respect to a vertical line perpendicular to the top surface of a MOSFET device 150. This double-angle approach provides a trade-off between smaller series resistance and increased HCI effects (from an LDD perspective). The values of θ typically differ for halo implants versus LDD region implants—for example, the tilt angle θ may be about 30° for halo implants, and about 10° for LDD implants. In the illustrated example, tilted implantation of dopants for halo implants 130 and LDD regions 132 is made only from the source S side of the MOSFET 150, such that the gate structure 112 “shadows” the drain D side. Accordingly, the halo implants 130 and LDD regions 132 on the drain D side underlap the gate structure 112. The resulting underlap junction on the drain D side improves BV_{DSS} and reduces HCI events due to the graded junction on the drain side D.

Despite the BV_{DSS} and HCI advantages of conventional asymmetric MOSFET devices for power applications. there is still a need for improved performance in such devices. The present invention addresses that need.

### SUMMARY

The present invention encompasses device structures and related fabrication methods for asymmetric MOSFETs that exhibit high BV_{DSS} and low HCI characteristics while substantially improving the poor sub-threshold slope and output resistance R_{OUT} characteristics common to conventional asymmetric MOSFET devices.

Embodiments are fabricated by implanting halo and/or LDD dopants only from the source-side of an asymmetric MOSFET using at least two different non-90° twist angles, each in a different quadrant. By implanting dopant at different twist angles, dopant is implanted within otherwise shadowed corners, thus essentially eliminating the parasitic transistors within such corners. Optionally, an extra implantation of halo/LDD dopants may be performed at a 90° twist angle. As a result, a non-90°, multi-twist implanted asymmetric MOSFET exhibits improved linearity and an essentially equivalent gain characteristic compared to conventional asymmetric MOSFETs. The novel asymmetric MOSFETs are quite suitable for applications, such as power amplifiers, which require good linearity and gain characteristics.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a stylized top plan view of a prior art IC structure for a single N-type MOSFET device.

FIG. 1B is a stylized cross-sectional view along line X-X of FIG. 1A.

FIG. 1C is a stylized cross-sectional view of an asymmetric MOSFET.

FIG. 2A is a top plan view of a first conventional asymmetric N-type MOSFET that has been asymmetrically implanted with dopants for halo implants and LDD regions.

FIG. 2B is a stylized cross-sectional view along line X-X of FIG. 2A.

FIG. 2C is a graph of drain current I_{D} versus gate voltage V_{G} for a conventional asymmetric N-type MOSFET device.

FIG. 2D is a top plan view of a second conventional asymmetric N-type MOSFET that has been asymmetrically implanted with dopants for halo implants and LDD regions.

FIG. 3A is a top plan view of a first asymmetric N-type MOSFET in accordance with the present invention.

FIG. 3B is a top plan view of a second asymmetric N-type MOSFET in accordance with the present invention.

FIG. 4 is a graph of MOSFET drain current I_{D} versus gate voltage V_{G} for a conventional 90°-implanted asymmetric MOSFET and a non-90°, dual-twist implanted asymmetric MOSFET fabricated in accordance with the teachings of the present invention.

FIG. 5 is a graph of MOSFET drain current I_{D} versus drain-source voltage V_{DS} at a selected gate voltage V_{G} for a conventional 90°-implanted asymmetric MOSFET and a non-90°, dual-twist implanted asymmetric MOSFET fabricated in accordance with the teachings of the present invention.

FIG. 6 is a graph of MOSFET transconductance Gm versus gate voltage V_{G} for a conventional 90° implanted asymmetric MOSFET and a non-90°, dual-twist implanted asymmetric MOSFET fabricated in accordance with the teachings of the present invention.

FIG. 7 is a graph of continuous wave (CW) error-vector magnitude (EVM) versus CW modulated output poser P_{OUT} for a conventional 90° implanted asymmetric MOSFET and a non-90°, dual-twist implanted asymmetric MOSFET.

FIG. 8 is a top plan view of a substrate that may be, for example, a printed circuit board or chip module substrate (e.g., a thin-film tile).

FIG. 9 is a process flow chart showing one method for making an asymmetric MOSFET.

FIG. 10 is a process flow chart showing one method for making an asymmetric MOSFET in and on an active region of an integrated circuit.

Like reference numbers and designations in the various drawings indicate like elements unless the context requires otherwise.

### DETAILED DESCRIPTION

The present invention encompasses device structures and related fabrication methods for asymmetric MOSFETs that exhibit high BV_{DSS} and low HCI characteristics while substantially improving the poor sub-threshold slope and output resistance R_{OUT} characteristics common to conventional asymmetric MOSFET devices.

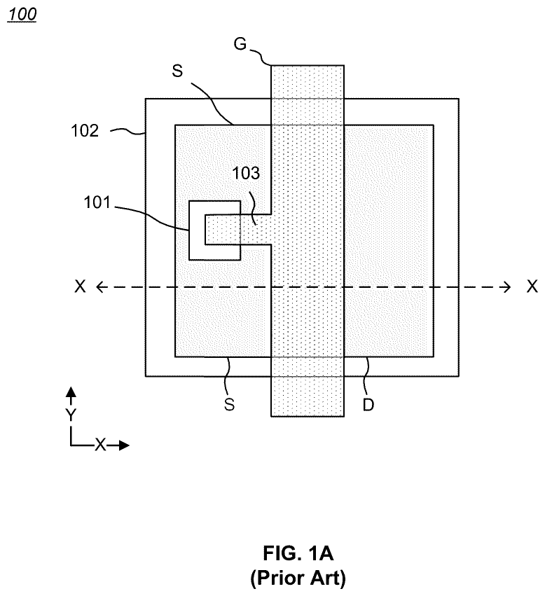

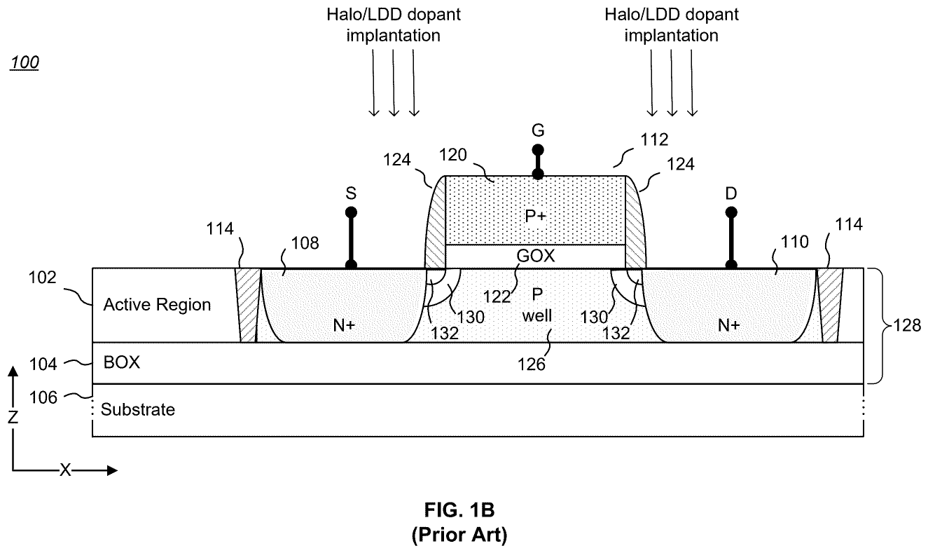

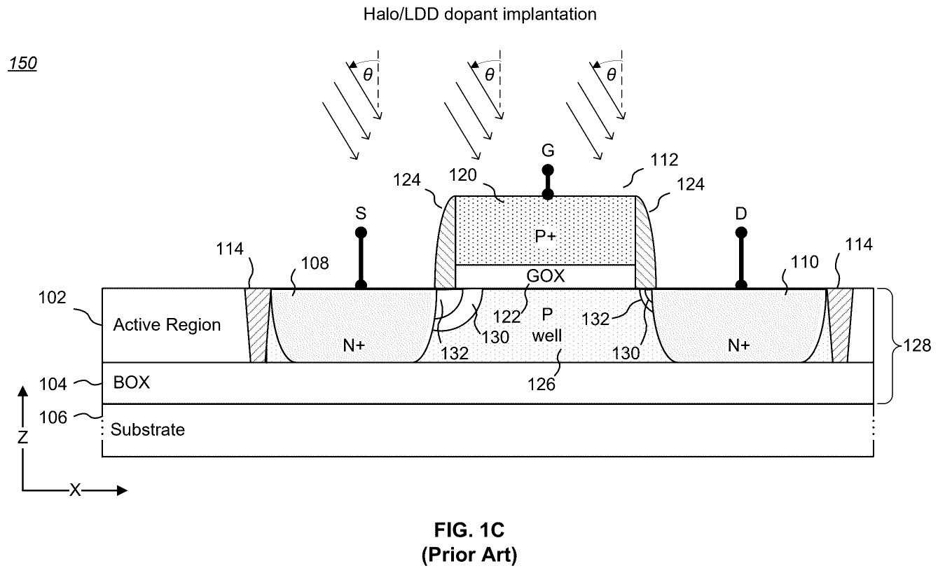

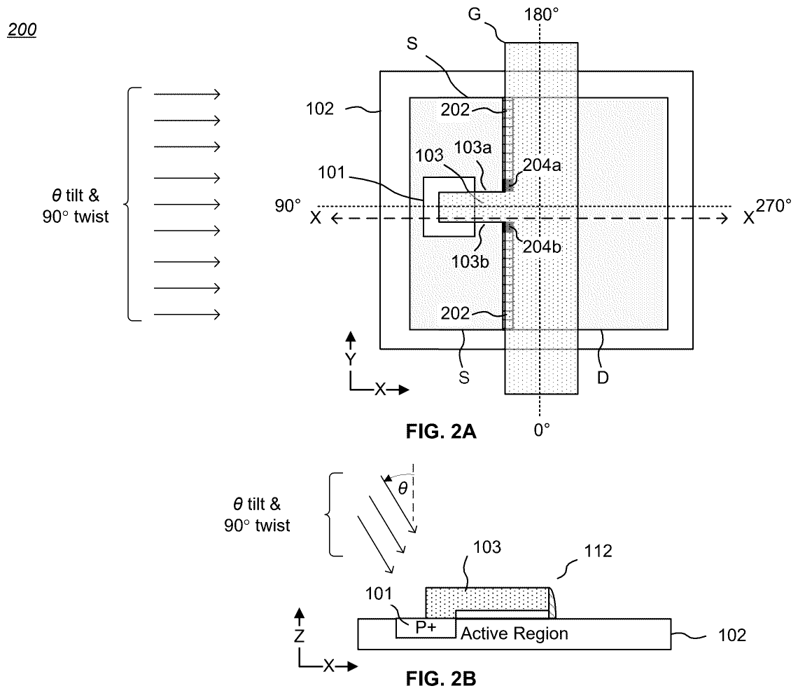

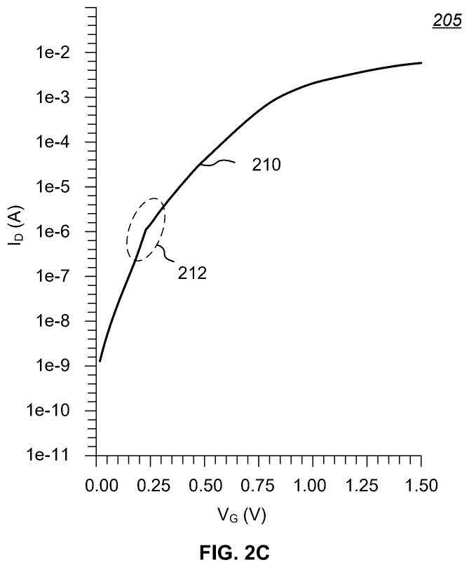

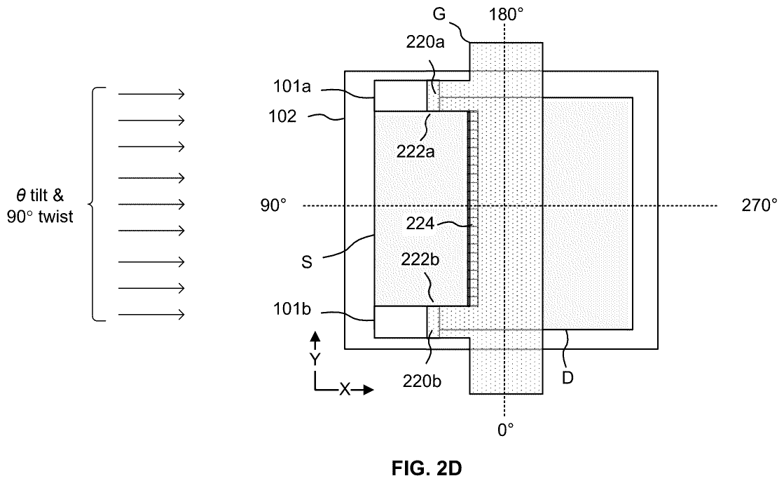

Conventional asymmetric N-type MOSFET devices suffer from poor sub-threshold slope and R_{OUT} due to the non-uniform halo implantation around the source-side central gate tab 103 (see FIG. 1A). For example, FIG. 2A is a top plan view of a first conventional asymmetric N-type MOSFET 200 that has been asymmetrically implanted with dopants for halo implants 130 and LDD regions 132 (see FIG. 1C). FIG. 2B is a stylized cross-sectional view along line X-X of FIG. 2A. In the illustrated example, the halo/LDD dopants are implanted only from the source S side of the gate structure G, with a tilt angle of θ relative to the Z dimension of the gate structure G (noting that θ may differ for halo implants versus LDD region implants) and a twist angle of 90° relative to the Y dimension of the gate structure G.

Because of shadowing by the body tie region 101 and the parallel orientation of the sides 103a, 103b of the central gate tab 103 with respect to the twist angle, the sides 103a, 103b of the central gate tab 103 receive a lower amount of implanted dopant compared to the source-side edge 202 of the gate structure G. In particular, the corners 204a, 204b formed by the sides 103a, 103b and source-side edge 202 of the gate structure G have reduced concentrations of dopant. The lower dopant concentration results in a lower threshold voltage V_{TH} for the corners 204a, 204b of the gate structure G. As a result, the corners 204a, 204b turn ON earlier than the rest of the transistor, causing the sub-threshold slope of I_{OFF} of the device to degrade. For example, FIG. 2C is a graph 205 of drain current I_{D} versus gate voltage V_{G} for a conventional asymmetric N-type MOSFET device. The low-dopant, low V_{TH} corners 204a, 204b of the gate structure G result in a tiny parasitic transistor at each of those corners that begins conducting at a V_{G} several 10's to 100's of mV below V_{TH} (i.e., the V_{TH} of the “normal” main transistor), resulting in a “kink” or “shoulder” region (within the dashed-oval 212) of the graph line 210—consequently, the leakage of the device suffers significantly.

In addition, the unidirectional halo/LDD implantation orientation results in reduced P-type dopant implantation underneath the polysilicon central gate tab 103, thus increasing resistance for holes between the device channel and the body tie region 101, thereby increasing floating body effects and decreasing ROUT.

The “low dopant region” problem of conventional asymmetric N-type MOSFET devices illustrated by FIGS. 2A and 2B occurs in other device geometries. For example, FIG. 2D is a top plan view of a second conventional asymmetric N-type MOSFET 218 that has been asymmetrically implanted with dopants for halo implants 130 and LDD regions 132 (see FIG. 1C). In the illustrated example, the single central gate tab 103 of FIG. 2A has been replaced by two polysilicon edge gate tabs 220a, 220b located near the Y-dimension ends of the gate structure G. The polysilicon edge gate tabs 220a, 220b overlay corresponding body tic regions 101a, 101b. Implantation of halo/LDD dopants with a tilt angle of θ (e.g., about 30° for halo implants and about 10° for LDD implants) and a twist angle of 90° results in the sides 222a, 222b of the edge gate tabs 220a, 220b receiving a lower amount of implanted dopant compared to the source-side edge 224 of the gate structure G.

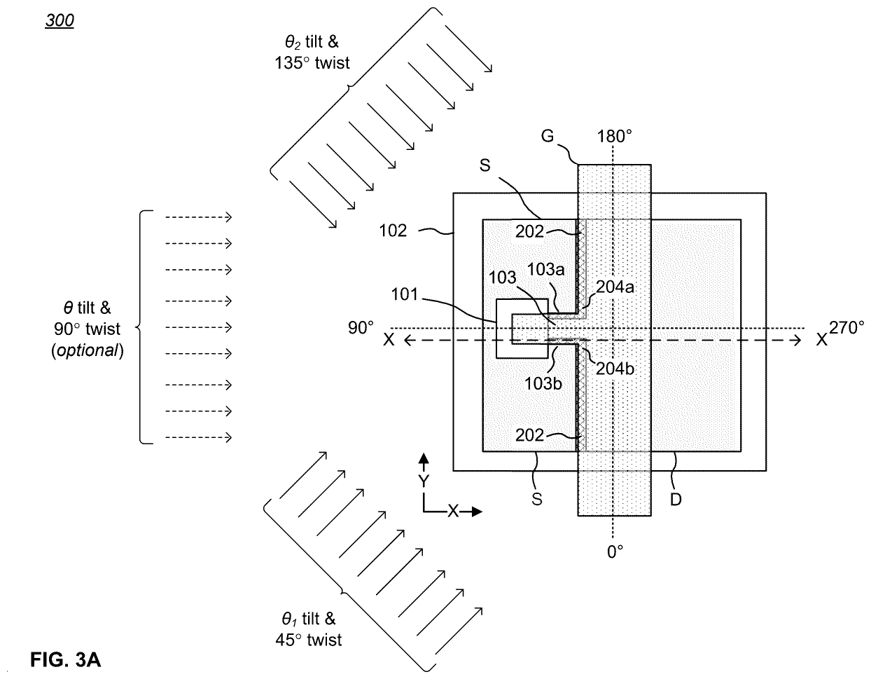

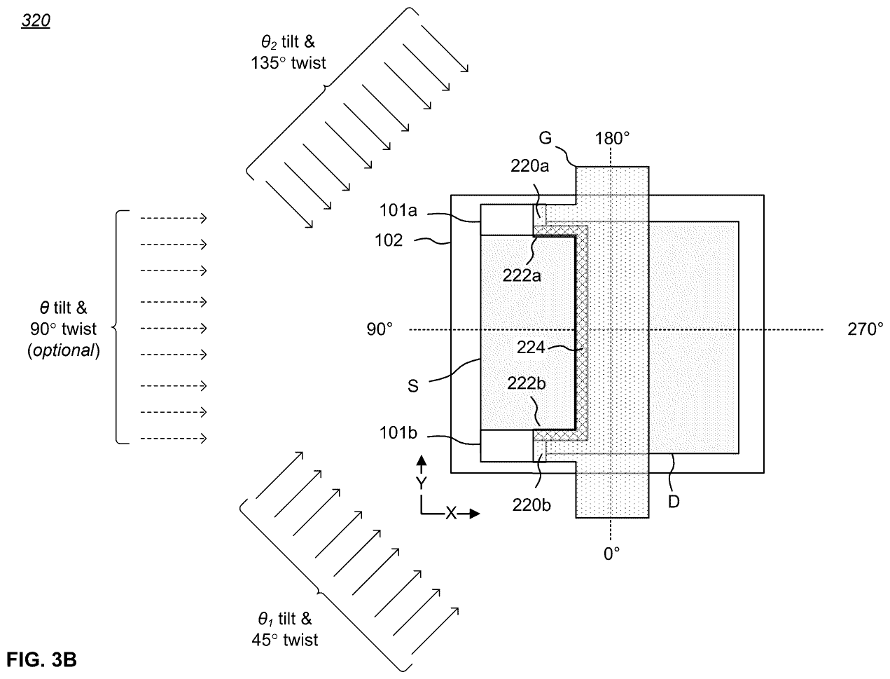

Applicant has found that instead of implanting halo/LDD dopants on the source-side of an asymmetric MOSFET at a conventional 90° twist angle (i.e., perpendicular to the Y dimension of the gate structure G), an asymmetric MOSFET with improved performance can be fabricated by implanting halo/LDD dopants at least two different non-90° twist angles, each in different quadrants (e.g., 0°-90° and) 90°-180°. For example, FIG. 3A is a top plan view of a first asymmetric N-type MOSFET 300 in accordance with the present invention. The example MOSFET 300 is of the type having a single central gate tab 103. The MOSFET 300 is asymmetrically implanted with dopants for halo regions and/or LDD regions by positioning the MOSFET 300 with respect to an implant source (e.g., a conventional ion implantation device, not shown) at a first twist angle in a first range of from about 0° to about 89° and at a second twist angle in a second range of from about 91° to about 180°. Preferred first and second ranges are 35°-55° and 125°-145°, respectively. As a practical matter in terms of equipment setup, the first twist angle may be set at 45° and the second twist angle may be set at 135°, as illustrated in FIG. 3A.

Implantation at the at least two twist angles may be performed sequentially (either order works), or concurrently if the implantation system provides two or more implant sources that may be set to suitable non-90° twist angles. Note that, optionally, an extra implantation of halo/LDD dopants may be performed at a 90° twist angle. In some embodiments, the tilt angle may differ for each twist angle (which need not be the same), and accordingly the concentration of dopant at each of the twist angles may need to be appropriately adjusted so that the V_{TH} value achieved for the parasitic corner transistors is equal to or greater than the V_{TH} value of the main transistor channel.

As should be apparent from the relative positions of the MOSFET 300 and the two different non-90° twist angles, the body tie region 101 will not shadow the corners 204a, 204b formed by the sides 103a, 103b and source-side edge 202 of the gate structure G. Accordingly, dopant will be implanted within the corners 204a, 204b, thus essentially eliminating the parasitic transistors described above with respect to FIG. 2B. As a result, the direct current (DC) and radio frequency (RF) characteristics of the MOSFET 300 are expected to improve. In particular, the RF linearity of the MOSFET 300 is improved.

The inventive technique may be used for other device geometries. For example, FIG. 3B is a top plan view of a second asymmetric N-type MOSFET 320 in accordance with the present invention. The illustrated example includes two polysilicon edge gate tabs 220a, 220b. Implantation of halo/LDD dopants at two different non-90° twist angles in different respective quadrants ensures that the sides 222a, 222b of the edge gate tabs 220a, 220b receive a suitable amount of implanted dopant to essentially eliminate the parasitic transistors described above with respect to FIG. 2D.

As should be clear, while the illustrated examples show only two different non-90° twist angles in different respective quadrants, more than two non-90° twist angles may be used to fabricate an asymmetric MOSFET. In addition, more than one tilt angle θ may be used to implant dopant into the halo and/or LDD regions. Further, while the examples have focused on N-type MOSFETs, the same techniques may be used to fabricate P-type MOSFETs.

Ideally, power MOSFETs should not appreciably alter or affect an RF signal. However, the solid-state nature of an IC causes undesirable interactions between regions of the IC, leading to such phenomena as leakage currents and parasitic capacitances, inductances, and resistances. Accordingly, MOSFETs generally behave less than ideally. Fortunately, small improvements in MOSFET structure and fabrication processes can result in significant performance improvements.

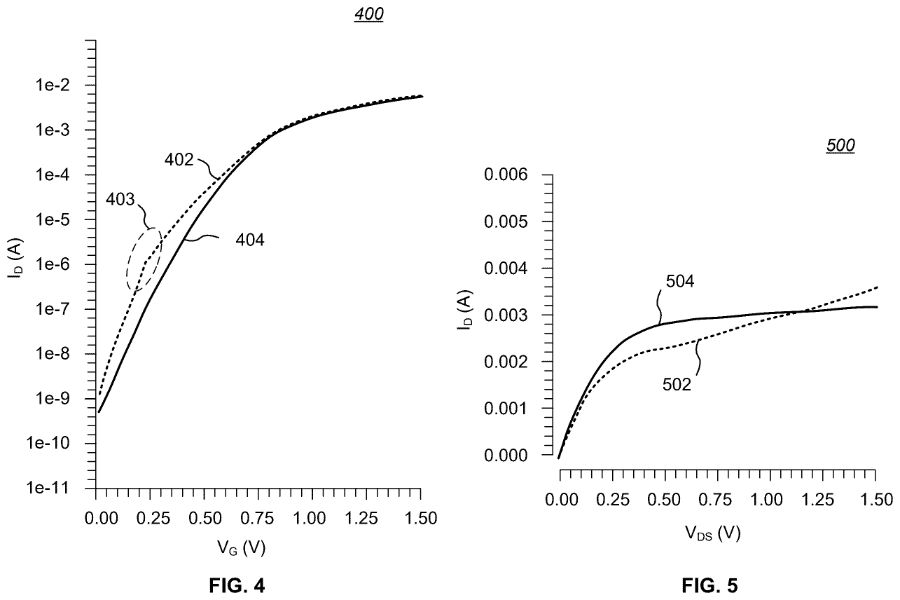

For example, FIG. 4 is a graph 400 of MOSFET drain current I_{D} versus gate voltage V_{G} for a conventional 90°-implanted asymmetric MOSFET (graph line 402) and a non-90°, dual-twist implanted asymmetric MOSFET (graph line 404) fabricated in accordance with the teachings of the present invention. Graph line 402 exhibits a shoulder region (within the dashed-oval 403) attributable to the low-dopant, low V_{TH} corners 204a, 204b of the gate structure G (see FIG. 2A) of the conventional asymmetric MOSFET, like the graph line 210 in FIG. 2C. In contrast, graph line 404 exhibits a smoother, more linear increase in I_{D} as a function of V_{G}.

FIG. 5 is a graph 500 of MOSFET drain current I_{D} versus drain-source voltage V_{DS} at a selected gate voltage V_{G} for a conventional 90°-implanted asymmetric MOSFET (graph line 502) and a non-90°, dual-twist implanted asymmetric MOSFET (graph line 504) fabricated in accordance with the teachings of the present invention. In a conventional asymmetric MOSFET, the body tie polysilicon gate extension (central gate tab 103 in FIG. 3A, edge gate tabs 220a, 220b in FIG. 3B) poses a relatively high resistance path for holes to be collected by the P+ body tie regions 101, 101a, 101b, thus increasing floating body effects and degrading device linearity, as shown by graph line 502. For a MOSFET configuration like that shown in FIG. 3A, the extra coverage of implanted halo dopant along the sides 103a, 103b of the central gate tab 103 provides a low resistance path for holes to travel to the body-to-source tie of the device. Similarly, for a MOSFET configuration like that shown in FIG. 3B, the extra coverage of implanted halo dopant along the sides 222a, 222b of the edge gate tabs 220a, 220b provides a low resistance path for holes to travel to the body-to-source tie of the device. The result is that asymmetric MOSFETs in accordance with the present invention exhibit very good linearity, as shown by graph line 504.

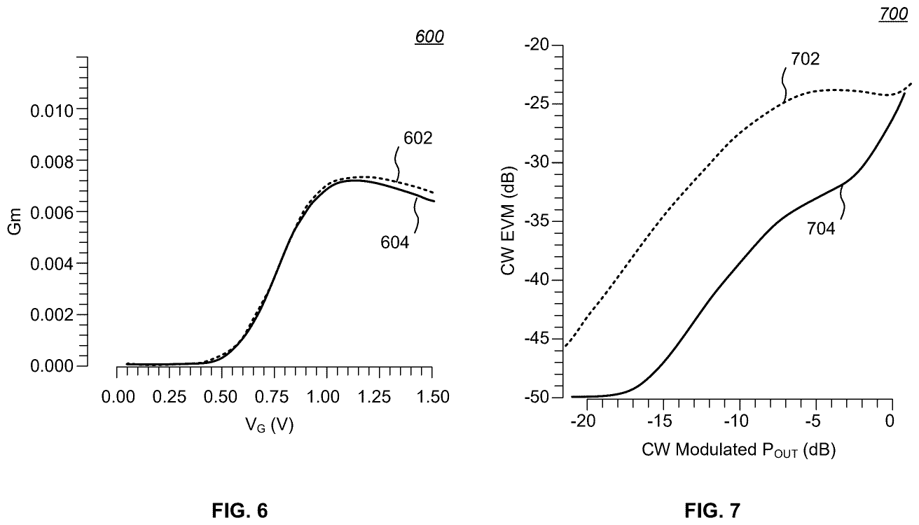

FIG. 6 is a graph 600 of MOSFET transconductance Gm versus gate voltage V_{G} for a conventional 90° implanted asymmetric MOSFET (graph line 602) and a non-90°, dual-twist implanted asymmetric MOSFET (graph line 604) fabricated in accordance with the teachings of the present invention. The very close overlap of the graph lines 602, 604 indicate that MOSFETs fabricated in accordance with the teachings of this disclosure exhibit no significant reduction in gain compared to a conventional design.

FIG. 7 is a graph 700 of continuous wave (CW) error-vector magnitude (EVM) versus CW modulated output power P_{OUT} for a conventional 90° implanted asymmetric MOSFET (graph line 702) and a non-90°, dual-twist implanted asymmetric MOSFET (graph line 704). As the graph lines indicate, embodiments of the present invention exhibit better EVM performance at higher output powers.

Consequently, compared to a conventional 90°-implanted asymmetric MOSFET, a non-90°, multi-twist implanted asymmetric MOSFET exhibits improved sub-threshold slope and output resistance R_{OUT} characteristics which result in improved linearity and an essentially equivalent gain characteristic. Furthermore, non-90°, multi-twist implanted asymmetric MOSFETs exhibit high BV_{DSS} and low HCI characteristics, making them quite suitable for applications, such as power amplifiers, that also require good linearity and gain characteristics.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

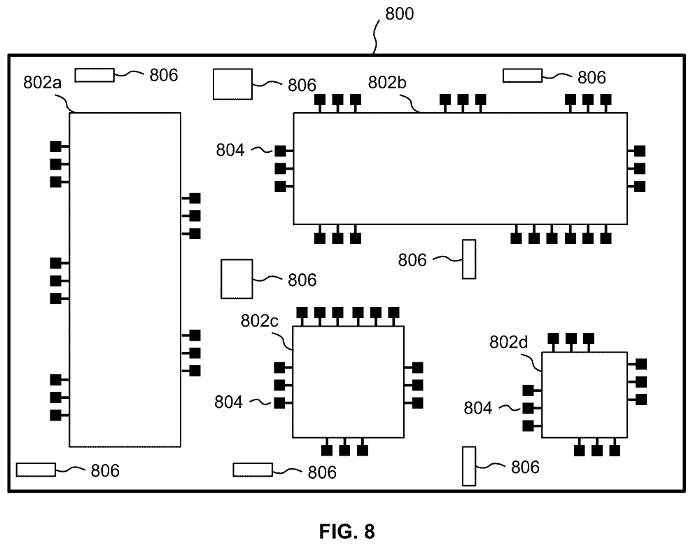

As one example of further integration of embodiments of the present invention with other components, FIG. 8 is a top plan view of a substrate 800 that may be, for example, a printed circuit board or chip module substrate (e.g., a thin-film tile). In the illustrated example, the substrate 800 includes multiple ICs 802a-802d having terminal pads 804 which would be interconnected by conductive vias and/or traces on and/or within the substrate 800 or on the opposite (back) surface of the substrate 800 (to avoid clutter, the surface conductive traces are not shown and not all terminal pads are labelled). The ICs 802a-802d may embody, for example, signal switches, active and/or passive filters, amplifiers (including one or more LNAs), and other circuitry. For example, IC 802b may incorporate one or more instances of a circuit that includes a non-90°, multi-twist implanted asymmetric MOSFET fabricated in accordance with the teachings of the present invention.

The substrate 800 may also include one or more passive devices 806 embedded in, formed on, and/or affixed to the substrate 800. While shown as generic rectangles, the passive devices 806 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 800 to other passive devices 806 and/or the individual ICs 802a-802d. The front or back surface of the substrate 800 may be used as a location for the formation of other structures.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

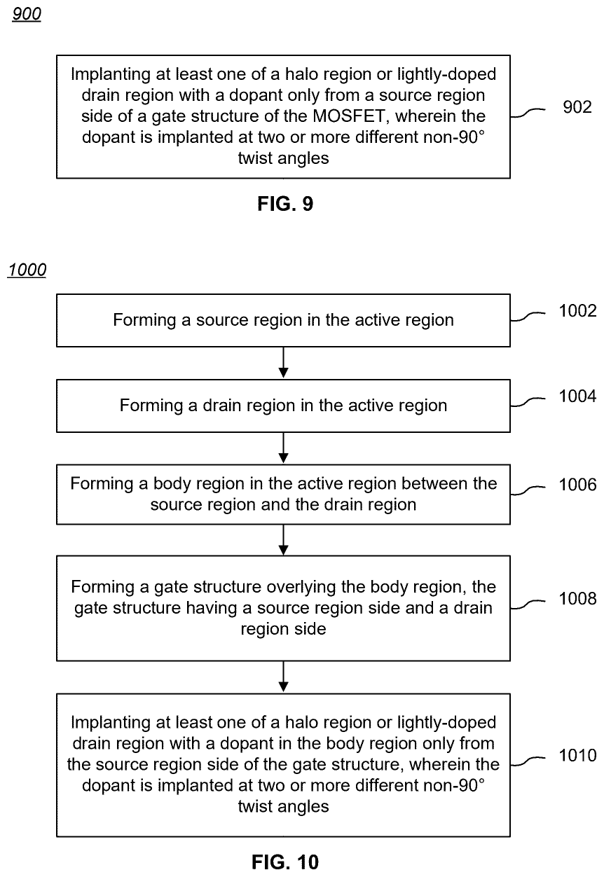

Another aspect of the invention includes methods for making high-performance asymmetric MOSFETs. For example, FIG. 9 is a process flow chart 900 showing one method for making an asymmetric MOSFET. The method includes: implanting at least one of a halo region or lightly-doped drain region with a dopant only from a source region side of a gate structure of the MOSFET, wherein the dopant is implanted at two or more different non-90° twist angles (Block 902).

As another example, FIG. 10 is a process flow chart 1000 showing one method for making an asymmetric MOSFET in and on an active region of an integrated circuit. The method includes: forming a source region in the active region (Block 1002); forming a drain region in the active region (Block 1004); forming a body region in the active region between the source region and the drain region (Block 1006); forming a gate structure overlying the body region, the gate structure having a source region side and a drain region side (Block 1008); and implanting at least one of a halo region or lightly-doped drain region with a dopant in the body region only from the source region side of the gate structure, wherein the dopant is implanted at two or more different non-90° twist angles (Block 1010).

Additional aspects of the above method may include one or more of the following: wherein implanting is at a first non-90° twist angle in a first quadrant with respect to the gate structure, and at a second non-90° twist angles in a second quadrant with respect to the gate structure; wherein implanting is at a first non-90° twist angle in a first range of about 0° to about 89° and at a second twist angle in a second range of from about 91° to about 180°; wherein implanting includes implanting a halo region with a dopant only from the source region side of the gate structure at a first tilt angle, and/or implanting a lightly-doped region with a dopant only from the source region side of the gate structure at a second tilt angle different from the first tilt angle; wherein the gate structure includes a central gate tab; wherein the gate structure includes two edge gate tabs, each located near a respective end of the gate structure; and/or further including implanting the dopant at a 90° twist angle.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as BiCMOS, LDMOS, BCD, GaAs HBT, GaN HEMT, GaAs pHEMT, MESFET, InP HBT, InP HEMT, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. An asymmetric metal-oxide-semiconductor field-effect transistor (MOSFET) including at least one of a halo region and/or lightly-doped drain region implanted with a dopant only from a source region side of a gate structure of the MOSFET, wherein the dopant is implanted at two or more different non-90° twist angles.

2. The MOSFET of claim 1, wherein a first non-90° twist angle is in a first quadrant with respect to the gate structure, and a second non-90° twist angles is in a second quadrant with respect to the gate structure.

3. The MOSFET of claim 1, wherein a first non-90° twist angle is in a first range of about 0° to about 89° and a second twist angle is in a second range of from about 91° to about 180°.

4. The MOSFET of claim 1, including a halo region implanted with a dopant at a first tilt angle, and a lightly-doped region implanted with a dopant at a second tilt angle different from the first tilt angle.

5. The MOSFET of claim 1, wherein the gate structure includes a central gate tab on the source side region of the gate structure.

6. The MOSFET of claim 1, wherein the gate structure includes two edge gate tabs, each located near a respective end of the gate structure on the source side region of the gate structure.

7. The MOSFET of claim 1, wherein the dopant is also implanted at a 90° twist angle.

8. An asymmetric metal-oxide-semiconductor field-effect transistor (MOSFET) including:
(a) a source region;
(b) a drain region;
(c) a body region between the source region and the drain region;
(d) a gate structure overlying the body region, the gate structure having a source region side and a drain region side;
(e) at least one of a halo region or lightly-doped drain region implanted with a dopant in the body region only from the source region side of the gate structure, wherein the dopant is implanted at two or more different non-90° twist angles.

9. The MOSFET of claim 8, wherein a first non-90° twist angle is in a first quadrant with respect to the gate structure, and a second non-90° twist angles is in a second quadrant with respect to the gate structure.

10. The MOSFET of claim 8, wherein a first non-90° twist angle is in a first range of about 0° to about 89° and a second twist angle is in a second range of from about 91° to about 180°.

11. The MOSFET of claim 8, including a halo region implanted with a dopant in the body region only from the source region side of the gate structure at a first tilt angle, and a lightly-doped region implanted with a dopant in the body region only from the source region side of the gate structure at a second tilt angle different from the first tilt angle.

12. The MOSFET of claim 8, wherein the gate structure includes a central gate tab.

13. The MOSFET of claim 8, wherein the gate structure includes two edge gate tabs, each located near a respective end of the gate structure.

14. The MOSFET of claim 8, wherein the dopant is also implanted at a 90° twist angle.

15. A method for making an asymmetric metal-oxide-semiconductor field-effect transistor (MOSFET) including implanting at least one of a halo region or lightly-doped drain region with a dopant only from a source region side of a gate structure of the MOSFET, wherein the dopant is implanted at two or more different non-90° twist angles.

16. The method of claim 15, wherein implanting is at a first non-90° twist angle in a first quadrant with respect to the gate structure, and at a second non-90° twist angles in a second quadrant with respect to the gate structure.

17. The method of claim 15, wherein implanting is at a first non-90° twist angle in a first range of about 0° to about 89° and at a second twist angle in a second range of from about 91° to about 180°.

18. The method of claim 15, wherein implanting includes implanting a halo region with a dopant only from the source region side of the gate structure at a first tilt angle, and/or implanting a lightly-doped region with a dopant only from the source region side of the gate structure at a second tilt angle different from the first tilt angle.

19. The method of claim 15, wherein the gate structure includes a central gate tab.

20. The method of claim 15, wherein the gate structure includes two edge gate tabs, each located near a respective end of the gate structure.

21. The method of claim 15, further including implanting the dopant at a 90° twist angle.

22.-28. (canceled)
